(19) United States
(12) Patent Application Publication
(10) Pub. No.: US 2015/0047894 A1
(43) Pub. Date: Feb. 19, 2015

(54) SHELL OF ELECTRONIC DEVICE AND METHOD OF MANUFACTURING THE SAME

(71) Applicants: HON HAI PRECISION INDUSTRY CO., LTD., NEW TAIPEI (TW); HONG FU JIN PRECISION INDUSTRY (WUHAN) CO., LTD., WUHAN (CN)

(72) Inventors: CHING-JOU CHEN, New Taipei (TW); WEN-CHIEH WANG, New Taipei (TW); WEN-CHIN LIN, New Taipei (TW)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/144,611

(22) Filed: Dec. 31, 2013

(30) Foreign Application Priority Data
Aug. 14, 2013 (TW) 102129090

(51) Int. Cl. H05K 9/00

(52) U.S. Cl. CPC H05K 9/0007
USPC 174/377; 29/602.1

(57) ABSTRACT

A shell of an electronic device includes a resin base formed by injecting molten resin into an injection mold, and a film layer including a base layer attached to the resin base and an electro magnetic interference shielding layer attached to the base layer and opposite to the resin base.

### TECHNICAL FIELD

The disclosure relates to electronic devices and, particularly to a shell of an electronic device.

### Description of Related Art

High frequency electromagnetic radiation easily enters the inside of the electronic equipment through the shells of the electronic equipment, causing harm to circuits of the electronic equipment, and may even causing the electronic equipment to malfunction.

### BRIEF DESCRIPTION OF THE DRAWINGS

FIG. 1 is a flowchart of an exemplary embodiment of a method for manufacturing a shell.

FIG. 2 is a cross-sectional view of a film for manufacturing the shell manufactured by the method of FIG. 1.

FIG. 3 is a cross-sectional view of the film of FIG. 2, which is processed by chemical vapor deposition.

FIG. 4 is a cross-sectional view of an injection mold with the film of FIG. 3 used in the method of FIG. 1.

FIG. 5 is similar to FIG. 4, but showing the injection mold closed.

FIG. 6 is a cross-sectional view of an embodiment of the shell manufactured by the method of FIG. 1.

FIG. 7 is an enlarged view of a circled part VII of FIG. 6.

FIG. 8 is similar to FIG. 7, but showing a cross-sectional view of another embodiment of the shell.

### DETAILED DESCRIPTION

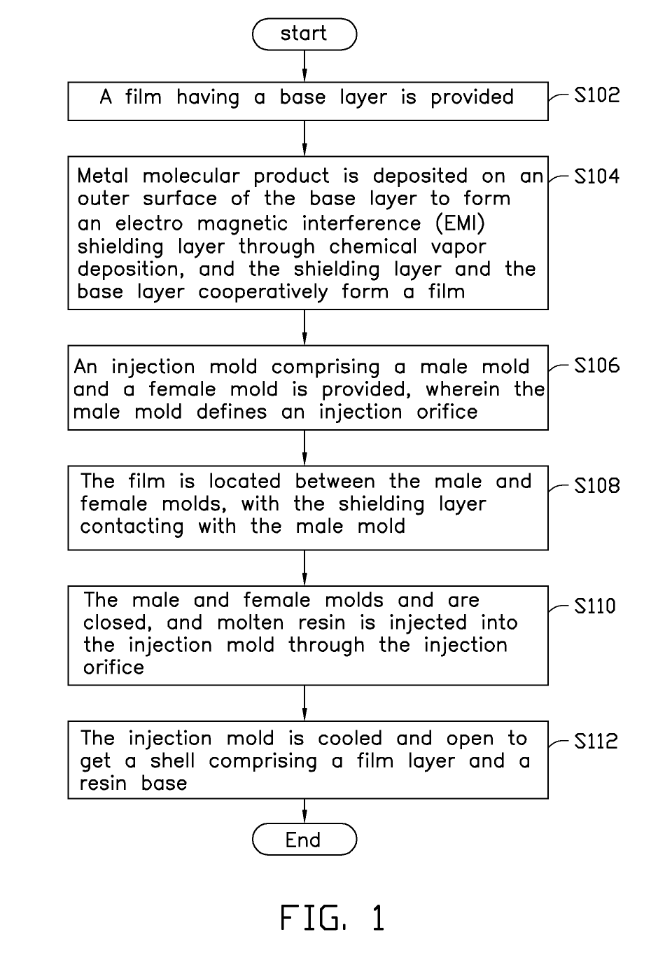

FIG. 1 shows an exemplary embodiment of a method to manufacture a shell. The method to manufacture the shell comprises the following steps.

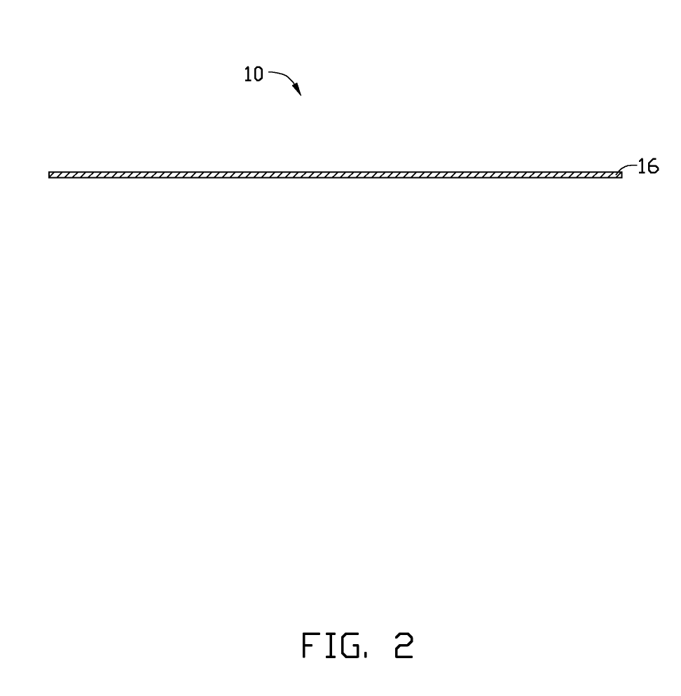

In step S102, a film 10 (as shown in FIG. 2) having a base layer 16 is provided.

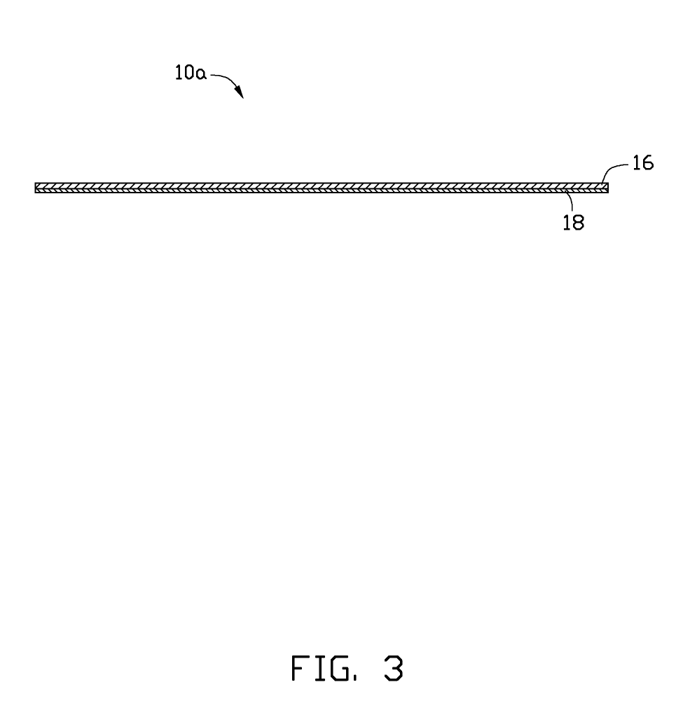

In step S104, metal molecular product is deposited on an outer surface of the base layer 16 to form an electro magnetic interference (EMI) shielding layer 18 through chemical vapor deposition, and the shielding layer 18 and the base layer 16 cooperatively form a film 10a, as shown in FIG. 3.

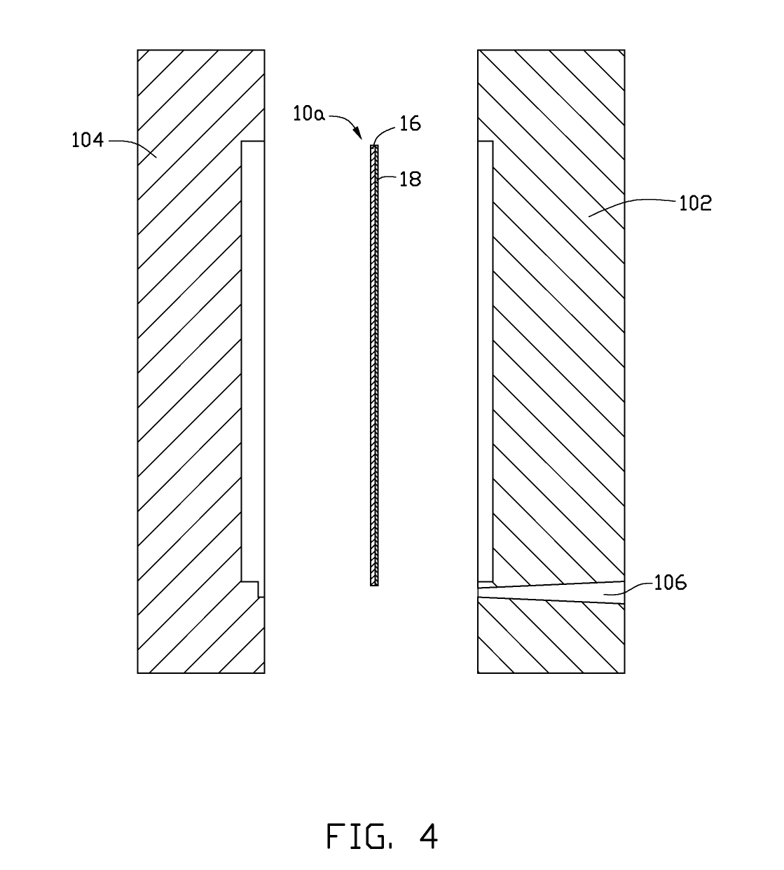

In step S106, an injection mold 100 comprising a male mold 102 and a female mold 104 is provided, wherein the male mold 102 defines an injection orifice 106, as shown in FIG. 4.

In step S108, the film 10a is located between the male and female molds 102, 104, with the shielding layer 18 contacting with the male mold 102, as shown in FIG. 4.

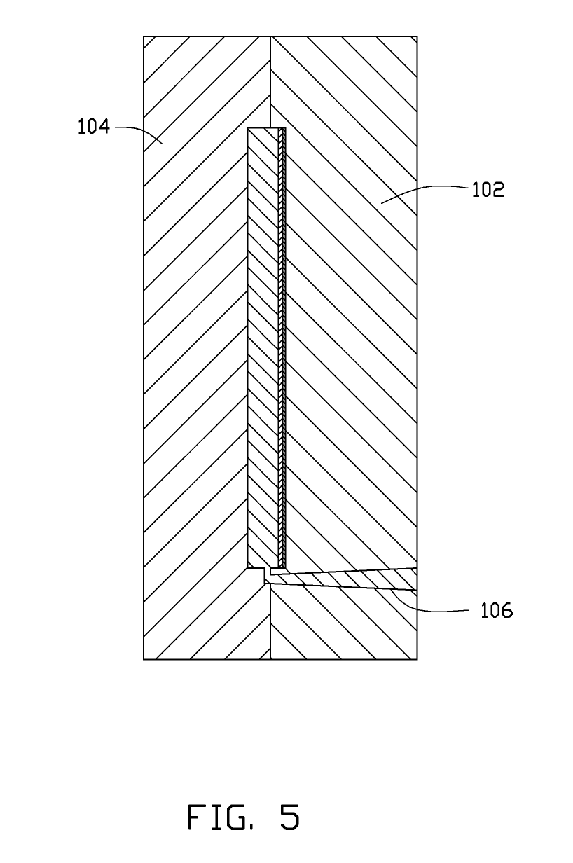

In step S110, the male and female molds 102 and 104 are closed, and molten resin is injected into the injection mold 100 through the injection orifice 106, as shown in FIG. 5. The resin may be made from at last one type of a plurality of resin materials comprising polycarbonate, polyethylene terephthalate, acrylic, oriented polypropylene, and polyvinyl chloride.

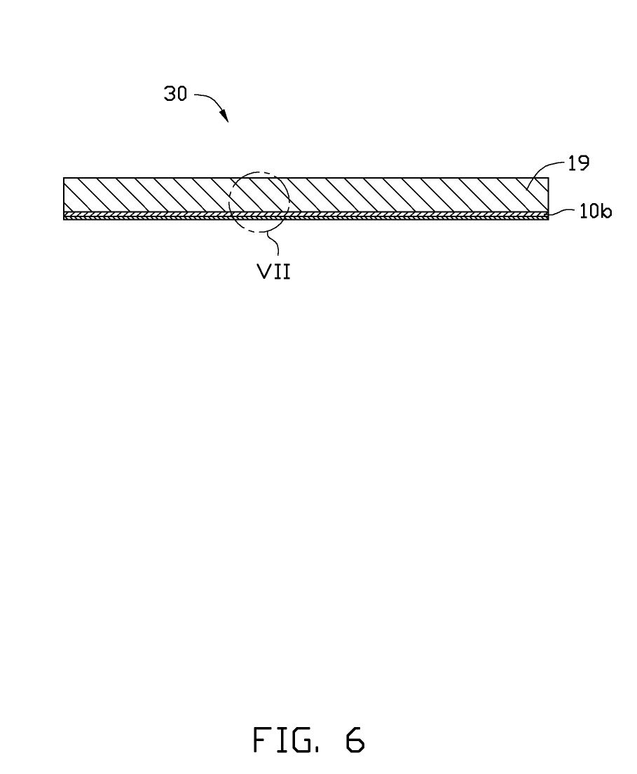

In step S112, the injection mold 100 is cooled and opened to get a shell 30 comprising a film layer 10b and a resin base 19, as shown in FIG. 6, the skin appearance of the shell is formed by the female mold 104.

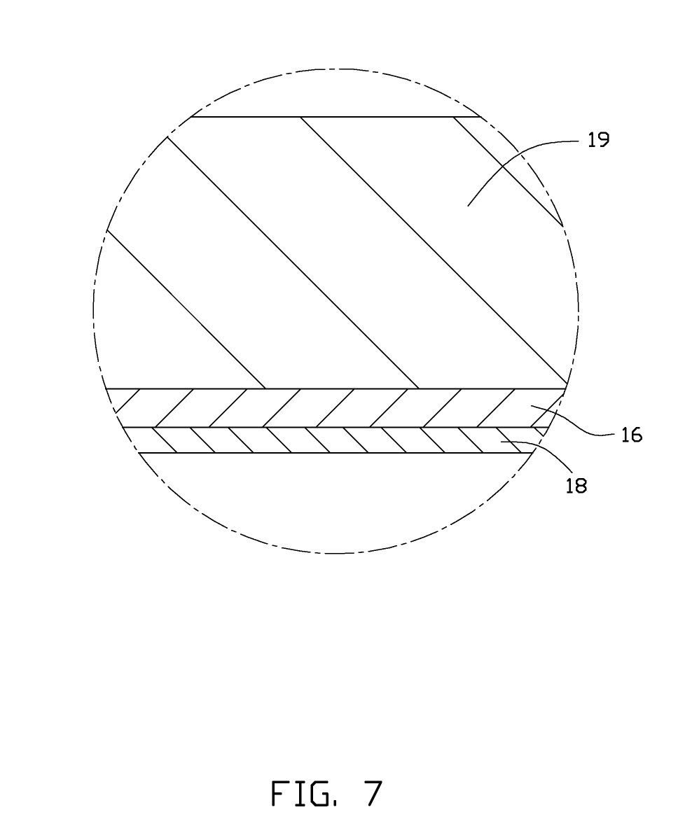

FIG. 7 shows that a first exemplary embodiment of the shell 30 manufactured by the above-mentioned method comprises a resin base 19 and a film layer 10b. The film layer 10b comprises a base layer 16 and a shielding layer 18. A skin appearance of the shell 30 is opposite to the shielding layer 18.

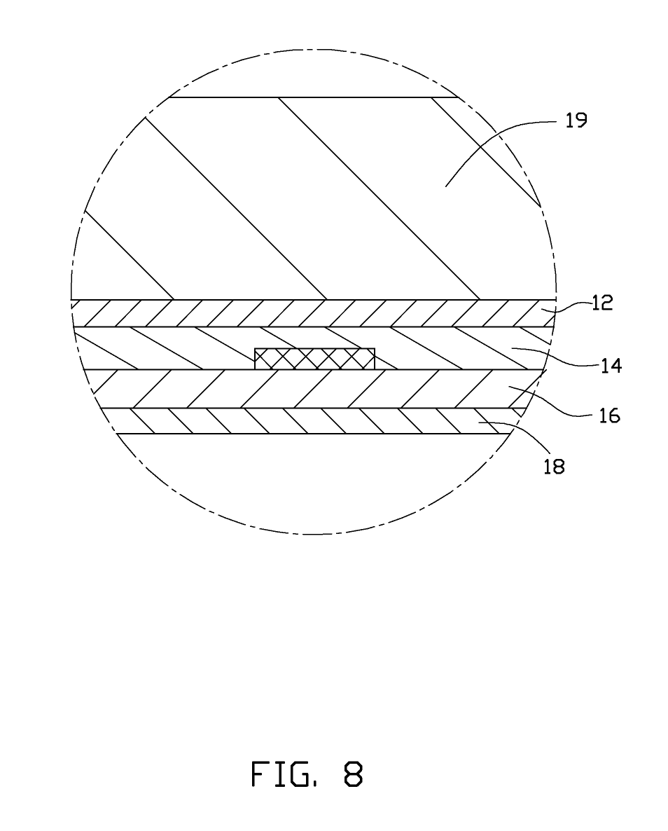

FIG. 8 shows that in another exemplary embodiment of the shell 30, the film layer 10b further comprises an adhering layer 12 and a pattern layer 14. The pattern layer 14 is formed on one side of the base layer 16 opposite to the shielding layer 18. The pattern layer 14 may be provided by printing ink on the base layer 16. A metal decorative layer can be provided as the pattern layer 14. The metal decorative layer may be aluminum, chromium, copper, nickel, indium, or tin, alone or combined, on the base layer 16 through either a vacuum evaporation or electroplating method. The adhering layer 12 is attached to the pattern layer 14 to adhere the film 10b to the resin base 19. The resin base 19 and the base layer 16 are transparent or semitransparent for showing the pattern layer 14.

In this embodiment, the shielding layer 18 can shield electro magnetic radial for the electronic device enclosed in the shell 30.

It is believed that the present embodiments and their advantages will be understood from the foregoing description, and it will be apparent that various changes may be made thereto without departing from the spirit and scope of the description or sacrificing all of its material advantages, the examples hereinbefore described merely being exemplary embodiments.

What is claimed is:

1. A method for forming a shell, the method comprising:
providing a film comprising a base layer;
forming an electro magnetic interference shielding layer on the base layer through chemical vapor deposition;
providing an injection mold comprising a male mold and a female mold;
putting the film between the male and female molds, with the shielding layer contacting with the male mold;
closing the male and female molds and injecting molten resin into the injection mold; and
cooling and opening the injection mold to get the shell.

2. The method of claim 1, wherein the male mold defines an injection orifice, the shielding layer contacts with the male mold.

3. A shell of an electronic device, comprising:
a resin base formed by injecting molten resin into an injection mold; and
a film layer comprising a base layer attached to the resin base and an electro magnetic interference shielding layer attached to the base layer and opposite to the resin base.

4. The shell of claim 3, wherein the film layer further comprises an adhering layer and a pattern layer, the pattern layer is formed on one side of the base layer opposite to the shielding layer, the adhering layer is attached to the pattern layer to adhere the film layer to the resin base.

5. The shell of claim 4, wherein the resin base and the base layer are transparent or semitransparent for showing the pattern layer.
